(19) United States
(12) Patent Application Publication
(10) Pub. No.: US 2026/0324257 A1
(43) Pub. Date: Oct. 15, 2026

(54) DISPLAY MODULE, MANUFACTURING METHOD THEREFOR AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventor: Yangpeng WANG, Beijing (CN)

(21) Appl. No.: 19/475,433

(22) PCT Filed: Sep. 11, 2024
(86) PCT No.: PCT/CN2024/118355

§ 371 Date: Oct. 15, 2025

(30) Foreign Application Priority Data
Oct. 30, 2023 (CN) 202311418326.1

(51) Int. Cl. H10K 59/80; H10K 102/00

(52) U.S. Cl. CPC H10K 59/873; H10K 2102/311

(57) ABSTRACT

A display module, a manufacturing method therefor, and a display device. The display module (100) comprises: a display panel (110), a protective layer (120), and an encapsulation layer (130). The display panel (110) comprises a display area (112) and a binding area (113) connected to the display area; the protective layer (120) covers the outer side of the binding area (113); the encapsulation layer (130) is arranged around the periphery of the display panel. One of the protective layer (120) and the encapsulation layer (130) is provided with positioning protrusions (140), and the other one thereof is provided with positioning grooves (150), the positioning protrusions (140) being embedded in the positioning grooves (150).

### CROSS-REFERENCE TO RELATED APPLICATIONS

The present application is a U.S. National Phase Entry of International Application No. PCT/CN2024/118355 having an international filing date of Sep. 11, 2024, which claims priority to Chinese Patent Application No. 202311418326.1, filed to the CNIPA on Oct. 30, 2023 and entitled “Display Module, Manufacturing Method Therefor and Display Device”. Contents of the above-identified applications are incorporated herein by reference.

### TECHNICAL FIELD

Embodiments of the present disclosure relate to, but are not limited to, the field of display technologies, and particularly relate to a display module and a manufacturing method therefor, and a display device.

### BACKGROUND

Display modules and display devices are widely used. Especially OLED screens are widely used because of their advantages such as self-illumination, low power consumption, thinness, winding ability, brilliant colors, high contrast, and fast response speed. However, since OLED materials themselves are vulnerable to water and oxygen, it is necessary to encapsulate the periphery of the display panel.

At present, after encapsulating the periphery of the display panel, the action force on the contact surface between the encapsulation layer and the display panel is likely to be poor, and the displacement is likely to occur by the action of an external force. The risk of defects increases since the action force on the contact surface between the encapsulation layer and the display panel is poor.

### SUMMARY

The following is a summary of subject matter described in the present disclosure in detail. This summary is not intended to limit the protection scope of claims.

Embodiments of the present disclosure provide a display module, a manufacturing method therefor, and a display device.

In a first aspect, a display module provided by an embodiment of the present disclosure includes: a display panel including a display area and a binding area connected to the display area; a protective layer covering an outer side of the binding area; and an encapsulation layer arranged around a periphery of the display panel. One of the protective layer and the encapsulation layer is provided with a positioning protrusion, the other of the protective layer and the encapsulation layer is provided with a positioning groove, and the positioning protrusion is embedded into the positioning groove.

In an exemplary embodiment of the present disclosure, when the protective layer is provided with the positioning protrusion, a connection area between the positioning protrusion and the protective layer is smaller than a projected area of the positioning protrusion on the protective layer.

In an exemplary embodiment of the present disclosure, when the protective layer is provided with positioning protrusion, a height of the positioning protrusion with respect to the protective layer is less than or equal to 300 um.

In an exemplary embodiment of the present disclosure, a maximum width of a projection surface of the positioning protrusion on the protective layer is less than or equal to 300 um.

In an exemplary embodiment of the present disclosure, a plurality of positioning protrusions are provided, and the plurality of positioning protrusions are disposed on the protective layer or the encapsulation layer.

In an exemplary embodiment of the present disclosure, two adjacent positioning protrusions are spaced apart by a distance of less than or equal to 5 um.

In an exemplary embodiment of the present disclosure, shapes of any two of the positioning protrusions are the same or different.

In an exemplary embodiment of the present disclosure, a cross-sectional shape of the positioning protrusion is at least one of a T-shape, an L-shape, a rectangular shape, a circular shape, a trapezoid shape, a triangular shape, and an arc shape.

In an exemplary embodiment of the present disclosure, the positioning protrusion is in printing connection with the positioning groove.

In an exemplary embodiment of the present disclosure, the display module further includes an adhesive layer and a cover plate, the adhesive layer adheres the cover plate and a display surface of the display panel, and a height sum of the positioning protrusion and the protective layer is smaller than spacing between the display panel and the cover plate.

In an exemplary embodiment of the present disclosure, when the protective layer is provided with the positioning protrusion, the positioning protrusion is in printing connection with the protective layer.

In an exemplary embodiment of the present disclosure, when the protective layer is provided with the positioning protrusion, the positioning protrusion and the protective layer are integrally formed by printing.

In an exemplary embodiment of the present disclosure, the protective layer and the positioning protrusion have the same material or different materials.

In a second aspect, an embodiment of the present disclosure provides a method for manufacturing a display module, including: providing a protective layer in a binding area of a display panel, wherein the protective layer is formed by printing or by coating; adhering a cover plate to a display surface of the display panel through an adhesive layer, printing a positioning protrusion on a side of the protective layer away from the binding area, and bending the binding area; and printing an encapsulation layer around the display panel so that the encapsulation layer forms a positioning groove that fits with the positioning protrusion.

In an exemplary embodiment of the present disclosure, the step of adhering the cover plate to the display surface of the display panel through the adhesive layer, printing the positioning protrusion on the side of the protective layer away from the binding area, and bending the binding area include: adhering the cover plate to the display surface of the display panel through the adhesive layer; bending the binding area provided with the protective layer; and printing the positioning protrusion on the side of the protective layer away from the binding area.

In an exemplary embodiment of the present disclosure, the step of adhering the cover plate to the display surface of the display panel through the adhesive layer, printing the positioning protrusion on the side of the protective layer away from the binding area, and bending the binding area include: printing the positioning protrusion on the side of the protective layer away from the binding area; adhering the cover plate to the display surface of the display panel through the adhesive layer; and bending the binding area provided with the protective layer and the positioning protrusion.

In a third aspect, an embodiment of the present disclosure provides a display device including the display module provided in the first aspect.

Other aspects of the present disclosure may be comprehended after the drawings and the detailed descriptions are read and understood.

### BRIEF DESCRIPTION OF DRAWINGS

FIG. 1 is a schematic structural diagram of a display module according to an embodiment of the present disclosure.

FIG. 2 is a schematic structural diagram of a display module according to another embodiment of the present disclosure.

FIG. 3 is a schematic structural diagram of a positioning protrusion with T-shaped cross section of a display module according to an embodiment of the present disclosure.

FIG. 4 is a schematic structural diagram of a positioning protrusion with circular cross section of a display module according to an embodiment of the present disclosure.

FIG. 5 is a schematic structural diagram of a positioning protrusion with trapezoidal cross section of a display module according to an embodiment of the present disclosure.

FIG. 6 is a flowchart of a method for manufacturing a display module according to an embodiment of the present disclosure.

FIG. 7 is a schematic structural diagram of step S100.

FIG. 8 is a flowchart of steps S212 to S216 in a method for manufacturing a display module according to an embodiment of the present disclosure.

FIG. 9 is a schematic structural diagram of step S212 in the method for manufacturing a display module according to the embodiment of the present disclosure.

FIG. 10 is a schematic structural diagram of step S214 in the method for manufacturing a display module according to the embodiment of the present disclosure.

FIG. 11 is a schematic structural diagram of step S216 in the method for manufacturing a display module according to the embodiment of the present disclosure.

FIG. 12 is a flowchart of steps S232 to S236 in a method for manufacturing a display module according to an embodiment of the present disclosure.

FIG. 13 is a schematic structural diagram of step S232 in the method for manufacturing a display module according to the embodiment of the present disclosure.

FIG. 14 is a schematic structural diagram of step S234 in the method for manufacturing a display module according to the embodiment of the present disclosure.

FIG. 15 is a schematic structural diagram of step S236 in the method for manufacturing a display module according to the embodiment of the present disclosure.

FIG. 16 is a schematic structural diagram of step S300 corresponding to steps S212 to S216 in the method for manufacturing a display module according to the embodiment of the present disclosure.

FIG. 17 is a schematic structural diagram of step S300 corresponding to steps S232 to S236 in the method for manufacturing a display module according to the embodiment of the present disclosure.

### DETAILED DESCRIPTION

Specific implementations of the present disclosure will be described further in detail below with reference to the accompanying drawings and embodiments. The following embodiments are intended to illustrate the present disclosure and are exemplary only, but are not intended to limit the scope of the present disclosure. The embodiments and features in the embodiments of the present disclosure may be randomly combined with each other if there is no conflict.

Technical solutions in embodiments of the present disclosure will be described clearly and completely with reference to the drawings in the embodiments of the present disclosure. The described embodiments are apparently only part of the embodiments of the present disclosure, rather than all of the embodiments. Based on the embodiments of the present disclosure, all other embodiments obtained by a person of ordinary skill in the art without paying any inventive effort are within the scope of protection of the present disclosure.

All directivity indications in the embodiment of the present disclosure are only used to explain the relative position relationship and motion situation and the like among a plurality of components under a specific attitude, and when the specific attitude is changed, the directivity indications are changed accordingly.

In the present disclosure, unless otherwise clearly specified and defined, terms “connection”, “fixed” and other terms should be broadly understood. For example, the term “fixed” may be connected fixedly or connected detachably, or integrated; or it can be mechanically connected or electrically connected; or directly connected, or be indirectly connected through an intermediary, or be internally connected between two elements or be interacted between two elements, unless otherwise clearly specified. Those of ordinary skills in the art may understand specific meanings of the aforementioned terms in the present disclosure according to situations.

In addition, descriptions relating to “first”, “second” and the like in the present disclosure are for descriptive purposes only and cannot be construed as indicating or implying their relative importance or implying the number of technical features indicated. Thus, the features defined by “first” or “second” may explicitly or implicitly include at least one of the features. In addition, the technical solutions in any embodiments may be combined with each other, but must be on the basis that the person of ordinary skill in the art can realize it. When the combination of technical solutions leads to mutual contradictions or cannot be realized, it should be considered that the combination of technical solutions does not exist and is not within the scope of protection claimed by the present disclosure.

In the present disclosure, “about” or “approximately” or the like means that a boundary is defined not so strictly and numerical values within process and measurement error ranges are allowed.

Display modules and display devices are widely used. Especially OLED screens are widely used because of their advantages such as self-illumination, low power consumption, thinness, winding ability, brilliant colors, high contrast, and fast response speed. However, since OLED materials themselves are vulnerable to water and oxygen, it is necessary to encapsulate the periphery of the display panel.

At present, after encapsulating the periphery of the display panel, the action force on the contact surface between the encapsulation layer and the display panel is likely to be poor, and the displacement is likely to occur by the action of an external force. The risk of defects increases since the action force on the contact surface between the encapsulation layer and the display panel is poor. The display module and the manufacturing method therefor, and the display device provided by the embodiments of the present disclosure can improve the above problems. The display module and the manufacturing method therefor, and the display device provided by the embodiments of the present disclosure can improve the action force between the encapsulation layer and the display panel when experiencing an external force, and reduce the risk of displacement between the encapsulation layer and the display panel when the entire display module is experiencing the external force, thereby reducing the risk of damage to the display module and prolonging the service life of the entire display module.

The present disclosure is described below in combination with the accompanying drawings and with reference to exemplary embodiments.

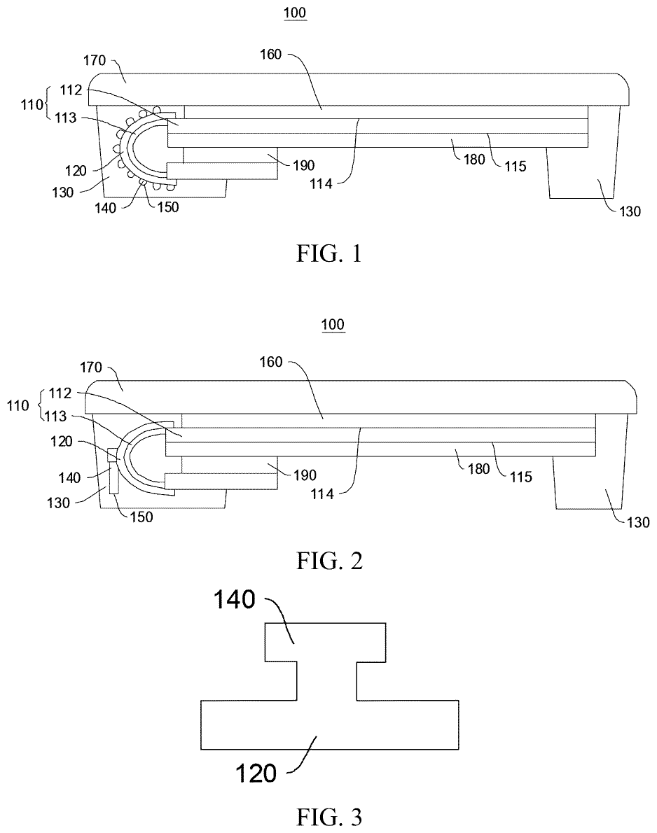

Referring to FIGS. 1 and 2, an embodiment of the present disclosure provides a display module 100. The display module 100 provided by the embodiment of the present disclosure can reduce the risk of displacement between an encapsulation layer 130 and a display panel 110 when the entire display module 100 is subjected to an external force, thereby reducing the risk of damage to the display module 100 and prolonging the service life of the entire display module 100.

In an embodiment of the present disclosure, the display module 100 includes a display panel 110, a protective layer 120, and an encapsulation layer 130. The display panel 110 includes a display area 112 and a binding area 113 connected to the display area 112. The protective layer 120 covers the outer side of the binding area 113. The encapsulation layer 130 is arranged around the periphery of the display panel 110. One of the protective layer 120 and the encapsulation layer 130 is provided with a positioning protrusion 140, and the other of the protective layer 120 and the encapsulation layer 130 is provided with a positioning groove 150, and the positioning protrusion 140 is embedded in the positioning groove 150.

In an embodiment of the present disclosure, the display panel 110 includes a display area 112 and a binding area 113, the binding area 113 is bent relative to the display area 112, and electronic components of the display panel 110 may be disposed in the binding area 113, that is, the electronic components of the display panel 110 are disposed in an inner side of the binding area 113. By disposing the electronic components of the display panel 110 in the inner side of the binding area 113, the arrangement of the electronic components can be facilitated, and all the electronic components are disposed on a side of a non-display surface 115 of the display area 112, so that the appearance of the entire display panel 110 is neat.

In an exemplary embodiment, the binding area 113 is substantially arc-shaped, the inner side of the binding area 113 refers to the interior of the arc, and the outer side of the binding area 113 refers to the exterior of the arc.

The protective layer 120 covers the outer side of the binding area 113, that is, the protective layer 120 is completely attached to the outer side of the binding area 113. The protective layer 120 functions in encapsulating and protecting the outer side of the binding area 113. The protective layer 120 may be disposed on the outer side of the binding area 113 by a coating process, or may be disposed on the outer side of the binding area 113 by printing, or may be disposed on the outer side of the binding area 113 by other manners, and the process of disposing the protective layer 120 on the binding area 113 may not be limited.

In addition, the periphery of the display panel 110 refers to all surfaces except a display surface 114 of the display panel 110, and the encapsulation layer 130 being arranged around the periphery of the display panel 110 means that the encapsulation layer 130 may be disposed on all surfaces except the display surface 114 of the display panel 110. The encapsulation layer 130 protects the other sides of the display panel 110 and plays a waterproof and anti-oxidation role.

The positioning protrusion 140 is provided on one of the protective layer 120 and the encapsulation layer 130, and the positioning groove 150 is provided on the other of the protective layer 120 and the encapsulation layer 130. Through the fitting between the positioning protrusion 140 and the positioning groove 150, the contact area between the binding area 113 and the encapsulation layer 130 is enhanced, thereby increasing the action area between the binding area 113 and the encapsulation layer 130. When subjected to an external force, by the fitting between the positioning protrusion 140 and the positioning groove 150, the action force between the protective layer 120 and the encapsulation layer 130 is increased, and the possibility of the relative displacement between the encapsulation layer 130 and the binding area 113 is reduced, thereby reducing the risk of damage to the display module 100, and prolonging the service life of the entire display module 100.

The positioning protrusion 140 may be provided on the protective layer 120, and the positioning groove 150 may be provided on the encapsulation layer 130. Alternatively, the positioning protrusion 140 may be provided on the encapsulation layer 130, and the positioning groove 150 may be provided on the protective layer 120. In the embodiments of the present disclosure, for convenience of description, the description is made by the example in which the positioning protrusion 140 is provided on the protective layer 120 and the positioning groove 150 is provided on the encapsulation layer 130, and the scheme in which the positioning protrusion 140 is provided on the encapsulation layer 130 and the positioning groove 150 is provided on the protective layer 120 can be inferred by same concept.

The shapes of the positioning protrusion 140 and the positioning groove 150 should be compatible with each other, that is, shapes that can be matched with each other. For example, when the outer shape of the positioning protrusion 140 is spherical, the shape of the positioning groove 150 is also spherical. When the shape of the positioning protrusion 140 is trapezoidal, the positioning groove 150 is also trapezoidal. Of course, in addition to the regular shape described above, the positioning protrusion 140 and the positioning groove 150 may have irregular shapes that can be matched.

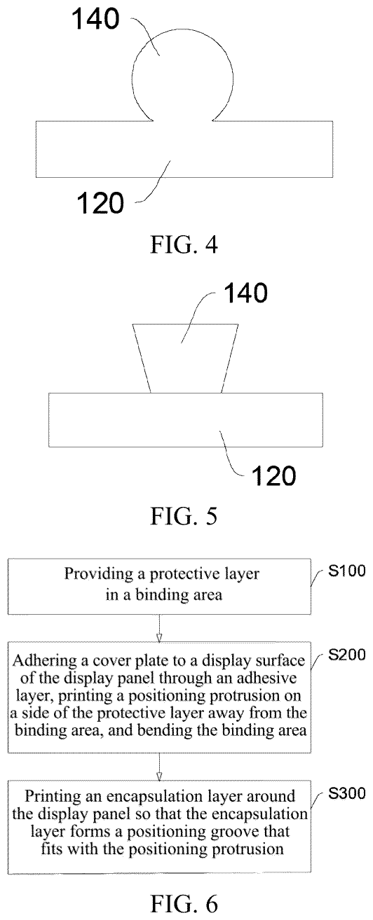

The cross-sectional shape of the positioning protrusion 140 may be at least one of a T-shape (as shown in FIG. 3), an L-shape, a rectangular shape, a circular shape (as shown in FIG. 4), a trapezoid shape (as shown in FIG. 5), a triangular shape and an arc shape. That is, the positioning protrusion 140 may have one of the above-described shapes or a combination of a plurality of the above-described shapes, and may be provided according to factors such as the actual structures and shapes of the protective layer 120 and the encapsulation layer 130.

The cross-sectional area of the positioning protrusion 140 refers to a cross-sectional area in a plane perpendicular to the protective layer 120.

Similarly, the number of positioning protrusions 140 and positioning grooves 150 may be set according to the size of the binding area 113. When the binding area 113 is relatively large, the number of positioning protrusions 140 and positioning grooves 150 may be set to be large, and when the binding area 113 is relatively small, the number of positioning protrusions 140 and positioning grooves 150 may be set to be small.

In some exemplary embodiments, when the protective layer 120 is provided with the positioning protrusion 140, a connection area between the positioning protrusion 140 and the protective layer 120 is smaller than a projected area of the positioning protrusion 140 on the protective layer 120.

When the positioning protrusions 140 are provided on the protective layer 120, the positioning grooves 150 are provided on the encapsulation layer 130. The connection area between the positioning protrusion 140 and the protective layer 120 refers to an area of the connection between the positioning protrusion 140 and the protective layer 120. If the connection area between the positioning protrusion 140 and the protective layer 120 is smaller than the projected area of the positioning protrusion 140 on the protective layer 120, it means that there is a position on the positioning protrusion 140 that is larger than the connection between the positioning protrusion 140 and the protective layer 120. In other words, that is, in a plurality of planes parallel to the protective layer 120, the cross-sectional area of the positioning protrusion 140 on at least one of the planes is larger than the connection area.

The connection area between the positioning protrusion 140 and the protective layer 120 is smaller than the projected area of the positioning protrusion 140 on the protective layer 120, which indicates that the outer shape of the positioning protrusion 140 is at least partially recessed inward in a direction of the positioning protrusion 140 towards the protective layer 120. As a result, when the positioning protrusion 140 is fitted with the positioning groove 150, the positioning protrusion 140 can be clamped within the positioning groove 150, which can improve the action force between the positioning protrusion 140 and the positioning groove 150, and reduce the risk of bad conditions between the encapsulation layer 130 and the protective layer 120 when subjected to an external force, thus prolonging the service life of the entire display module 100.

In an exemplary embodiment, the outer shape of the positioning protrusion 140 being at least partially recessed inward indicates that a part of an outer peripheral surface of the positioning protrusion 140 is recessed inward in the direction towards the protective layer 120, or the whole outer peripheral surface of the positioning protrusion 140 may be entirely recessed inward in the direction towards the protective layer 120.

Alternatively, the outer peripheral surface of the positioning protrusion 140 may have a plurality of inward recessed regions in the direction towards the protective layer 120. The larger the number of inward recessed regions, the greater the action force between the positioning protrusion 140 and the positioning groove 150, and the smaller the risk of bad conditions between the encapsulation layer 130 and the protective layer 120 when subjected to an external force.

In some embodiments, there are a plurality of positioning protrusions 140, and the plurality of positioning protrusions 140 are disposed on the protective layer 120 or the encapsulation layer 130.

When the positioning protrusions 140 are provided on the protective layer 120 and the positioning grooves 150 are provided on the encapsulation layer 130, the plurality of positioning protrusions 140 are provided on the protective layer 120. When the positioning protrusions 140 are provided on the encapsulation layer 130 and the positioning grooves 150 are provided on the protective layer 120, the plurality of positioning protrusions 140 are provided on the encapsulation layer 130. The case where the plurality of positioning protrusions 140 are provided on the protective layer 120 will be described as an example. The case where the plurality of positioning protrusions 140 are provided on the encapsulation layer 130 can be inferred by same concept.

The plurality of positioning protrusions 140 are provided on the protective layer 120, and the plurality of positioning protrusions 140 may be arranged continuously, or may be arranged at intervals. The continuous arrangement means that two adjacent positioning protrusions 140 may be connected. The arrangement at intervals means that there is a gap between two adjacent positioning protrusions 140.

The plurality of positioning protrusions 140 may be arranged in a matrix on the protective layer 120, or may be arranged on the protective layer 120 in another manner, and the arrangement manner may not be limited.

In an exemplary embodiment, sizes of the plurality of positioning protrusions 140 may be the same or different, which may not be limited in the present disclosure.

The shapes of any two positioning protrusions 140 are the same or different. That is, the shapes of the plurality of positioning protrusions 140 may all be the same, or the plurality of positioning protrusions 140 may have a plurality of different shapes. The cross section of some positioning protrusions 140 may be T-shaped, the cross section of some positioning protrusions 140 may be L-shaped, the cross section of some positioning protrusions 140 may be spherical, and the cross section of some positioning protrusions 140 may be triangular, or a combination of the above shapes.

Alternatively, since the positioning protrusion 140 is embedded in the positioning groove 150, the shape of the positioning groove 150 should be adapted to the shape and size of the positioning protrusion 140. Therefore, the shape and size of the positioning groove 150 can be inferred according to the shape and size of the positioning protrusion 140.

In some exemplary embodiments, two adjacent positioning protrusions 140 are spaced apart by a distance of less than or equal to 5 um.

The size of the whole display module 100 is relatively small. When the spacing distance between the two adjacent positioning protrusions 140 is too large, the number of positioning protrusions 140 on the protective layer 120 will be small, so that the overall contact area between the positioning protrusions 140 and the positioning grooves 150 will be small. If the spacing distance between the two adjacent positioning protrusions 140 is less than or equal to 5 um, the contact area between a single positioning protrusion 140 and a single positioning groove 150 can be ensured, and the number of positioning protrusions 140 can be increased. Therefore, the overall contact area between the positioning protrusions 140 and the positioning grooves 150 is increased, the risk of displacement between the encapsulation layer 130 and the display panel 110 when the entire display module 100 is subjected to an external force can be reduced, and the risk of damage to the display module 100 is reduced, thereby prolonging the service life of the entire display module 100.

The spacing distance between two adjacent positioning protrusions 140 may be one of 1 um, 2 um, 3 um, 4 um, and 5 um.

In some exemplary embodiments, the display module 100 further includes an adhesive layer 160 and a cover plate 170, and the adhesive layer 160 adheres the cover plate 170 to the display surface 114 of the display panel 110. A height sum of the positioning protrusion 140 and the protective layer 120 is smaller than spacing between the display panel 110 and the cover plate 170.

The adhesive layer 160 is used to adhere the cover plate 170 and the display surface 114, and the positioning protrusions 140 are provided on the binding area 113. When the positioning protrusions 140 are formed on the protective layer 120 before the binding area 113 is bent, in order to avoid interference between the positioning protrusions 140 and the cover plate 170, the height sum of the positioning protrusion 140 and the protective layer 120 is smaller than the spacing between the display panel 110 and the cover plate 170, that is, smaller than a thickness of the adhesive layer 160.

In manufacturing the display module 100, the cover plate 170 is generally adhered to the display surface 114 of the display panel 110 through the adhesive layer 160, and then the binding area 113 is bent to the non-display surface 115 of the display panel 110 (the display surface 114 and the non-display surface 115 are located on two opposite sides of the display area 112, respectively). When disposing the positioning protrusions 140 before the binding area 113 is bent, it is necessary to consider the case where the positioning protrusions 140 interfere with the cover plate 170. When disposing the positioning protrusions 140 after the binding area 113 is bent, the height of the positioning protrusion 140 is not limited by the above-described case.

The height of the positioning protrusion 140 is a height at which the positioning protrusion 140 protrudes from the protective layer 120, that is, the height of the positioning protrusion 140 is a height of the positioning protrusion 140 with respect to the protective layer 120. The height of the protective layer 120 can be regarded as the thickness of the protective layer 120, and the height sum of the positioning protrusion 140 and the protective layer 120 is the height of the positioning protrusion 140 with respect to the protective layer 120 plus the thickness of the protective layer 120.

In some exemplary embodiments, the thickness of the adhesive layer 160 is less than or equal to 300 um, and a thickness of the protective layer 120 is generally negligible. Therefore, the height of the positioning protrusion 140 may be less than or equal to 300 um. The interference between the positioning protrusion 140 and the cover plate 170 can be avoided as much as possible.

Alternatively, when the binding area 113 is bent first and then the positioning protrusions 140 are disposed, the height of the positioning protrusion 140 may be set to be less than or equal to 300 um. The height of the positioning protrusion 140 is less than or equal to 300 um, which can adapt to the size of the entire display module 100. When the positioning protrusion 140 is set to be relatively large, the positioning protrusion 140 will protrude outside the encapsulation layer 130, and the size of the positioning protrusion 140 is relatively large, and the number of positioning protrusions 140 provided on the protective layer 120 is relatively small. This results in the same bad conditions when the local regions of the encapsulation layer 130 and the protective layer 120 are impacted by an external force. The height of the positioning protrusion 140 can be set to be less than or equal to 300 um, so that the contact area between the single positioning protrusion 140 and the single positioning groove 150 can be ensured, and the positioning protrusions 140 can be provided at a plurality of positions on the protective layer 120 as much as possible, thereby reducing the risk of bad conditions in the entire display module 100 as much as possible, thereby prolonging the service life of the display module 100.

The height of the positioning protrusion 140 may be one of 50 um, 100 um, 150 um, 200 um, 250 um, and 300 um. The heights of the plurality of positioning protrusions 140 may be different or may be the same.

As for the size of the single positioning protrusion 140, a maximum width of the projected area of the positioning protrusion 140 on the protective layer 120 is less than or equal to 300 um. When the size of the positioning protrusion 140 is set to be relatively large, the number of positioning protrusions 140 on the protective layer 120 is relatively small. Due to the different shapes of the positioning protrusions 140, a maximum spacing distance between two adjacent positioning protrusions 140 is increased, and movement between the positioning protrusions 140 and the positioning grooves 150 is easy to occur when subjected to a large force. When the maximum width of the projected area of the positioning protrusion 140 on the protective layer 120 is less than or equal to 300 um, the contact area between the positioning protrusion 140 and the positioning groove 150 can be ensured, and the number of the positioning protrusions 140 can be ensured. Additionally, the total contact area between the positioning protrusions 140 and the positioning grooves 150 can be improved, and the risk of bad conditions in the entire display module 100 can be reduced as much as possible, thereby prolonging the service life of the display module 100

The maximum width of the projected area of the positioning protrusion 140 on the protective layer 120 may be one of 50 um, 100 um, 150 um, 200 um, 250 um, and 300 um. The maximum widths of the projection areas of the plurality of positioning protrusions 140 on the protective layer 120 may be different or may be the same.

In some exemplary embodiments, the positioning protrusions 140 are in printing connection with the positioning grooves 150.

The positioning protrusion 140 and the positioning groove 150 are connected by printing. In an exemplary embodiment, after the binding area 113 is bent and the positioning protrusions 140 are provided on the protective layer 120, the encapsulation layer 130 is printed around the periphery of the display panel 110 by printing. The printing manner has high accuracy, and the gap between two adjacent positioning protrusions 140 can be embedded with printing material, so that the printing material can cover the periphery of the positioning protrusions 140, and the positioning grooves 150 in which the positioning protrusions 140 are embedded can be formed, thereby increasing the contact area between the positioning protrusions 140 and the positioning grooves 150.

That is, the encapsulation layer 130 is disposed on the protective layer 120 by printing. Since the positioning protrusions 140 protrude from the protective layer 120 during printing, the shape of the positioning protrusion 140 can be adapted by filling the periphery of the positioning protrusion 140 with printing material. By forming the positioning groove 150 adapted to the positioning protrusion 140 on the encapsulation layer 130, the adaption between the positioning protrusion 140 and the positioning groove 150 can be improved, and the mismatch between the positioning protrusion 140 and the positioning groove 150 can be reduced as much as possible. Additionally, the contact area between the positioning protrusion 140 and the positioning groove 150 can be increased, and the risk of bad conditions occurring in the entire display module 100 can be reduced as much as possible, thereby prolonging the service life of the display module 100.

In some embodiments, when the protective layer 120 is provided with the positioning protrusions 140, the positioning protrusions 140 are in printing connection with the protective layer 120.

When the positioning protrusions 140 are disposed after the binding area 113 is bent, the positioning protrusions 140 may be connected to the protective layer 120 by printing, that is, the positioning protrusions 140 may be in printing connection with the protective layer 120. A coating material may be first coated on the outer side of the binding area 113 to form the protective layer 120 on the outer side of the binding area 113. The positioning protrusions 140 are then printed on a side of the protective layer 120 away from the binding area 113.

That is, in this case, the positioning protrusions 140 and the protective layer 120 are separately formed, and the protective layer 120 may be formed by applying a coating material on the binding area 113 before the binding area 113 is bent. After the binding area 113 is bent, the positioning protrusions 140 are printed on the protective layer 120, and finally the encapsulation layer 130 is printed below the cover plate 170 and around the periphery of the display panel 110.

When the positioning protrusions 140 and the protective layer 120 are separately formed, different materials may be used for the positioning protrusions 140 and the protective layer 120. The protective layer 120 may be made of a coating material, and the positioning protrusion 140 may be made of a printing material. This may be adapted to a case where the height of the positioning protrusion 140 is larger than the gap between the display surface 114 and the cover plate 170. In this case, the coating material is coated on the binding area 113 to form the protective layer 120, the binding area 113 is then bent, the positioning protrusions 140 are printed on the protective layer 120 after the binding area 113 is bent, and finally the encapsulation layer 130 is printed around the periphery of the display panel 110.

In addition, the positioning protrusions 140 and the protective layer 120 may be made of the same material. The protective layer 120 may be printed and formed in the binding area 113 by printing, then the binding area 113 is bent, and then the positioning protrusions 140 are printed on the protective layer 120 after bending, and finally the encapsulation layer 130 is printed around the periphery of the display panel 110.

In some other exemplary embodiments, when the protective layer 120 is provided with the positioning protrusions 140, the positioning protrusions 140 and the protective layer 120 are integrally formed by printing.

The positioning protrusions 140 and the protective layer 120 can be directly formed by printing material, which is suitable for the case in which the height sum of the positioning protrusion 140 and the protective layer 120 is smaller than the spacing distance between the display surface 114 and the cover plate 170. The protective layer 120 and the positioning protrusions 140 are integrally formed in the binding area 113 by printing first, and the positioning protrusions 140 will not interfere with the cover plate 170 because the height sum of the positioning protrusion 140 and the protective layer 120 is smaller than the spacing distance between the display surface 114 and the cover plate 170.

In this case, the same printing material may be used for the protective layer 120 and the positioning protrusions 140. The protective layer 120 and the positioning protrusions 140 may be integrally printed on the outside of the binding area 113, the binding area 113 provided with the protective layer 120 and the positioning protrusions 140 is then bent, and finally the encapsulation layer 130 may be printed around the periphery of the display panel 110 to encapsulate the display panel 110.

In some exemplary embodiments, the display module 100 further includes a back film 180 disposed on the non-display surface 115 of the display area 112 and a spacer 190 disposed between the back film 180 and the binding area 113.

In summary, in the display module 100 provided by the embodiment of the present disclosure, the positioning protrusions 140 are provided on one of the protective layer 120 and the encapsulation layer 130, and the positioning grooves 150 are provided on the other of the protective layer 120 and the encapsulation layer 130. Through the fitting between the positioning protrusions 140 and the positioning grooves 150, the contact area between the binding area 113 and the encapsulation layer 130 is enhanced, thereby increasing the action area between the binding area 113 and the encapsulation layer 130. When subjected to an external force, by the fitting between the positioning protrusions 140 and the positioning grooves 150, the action force between the protective layer 120 and encapsulation layer 130 is increased, the possibility of the relative displacement between the encapsulation layer 130 and binding area 113 is reduced, the risk of damage to the display module 100 is reduced, thereby prolonging the service life of the entire display module 100.

An embodiment of the present disclosure also provides a method for manufacturing a display module. The method for manufacturing a display module according to the embodiment of the present disclosure is mainly used for manufacturing the display module 100 described above. The method for manufacturing a display module according to the embodiment of the present disclosure can reduce the risk of displacement between the encapsulation layer 130 and the display panel 110 when the entire display module 100 is subjected to an external force, thereby reducing the risk of damage to the display module 100 and prolonging the service life of the entire display module 100.

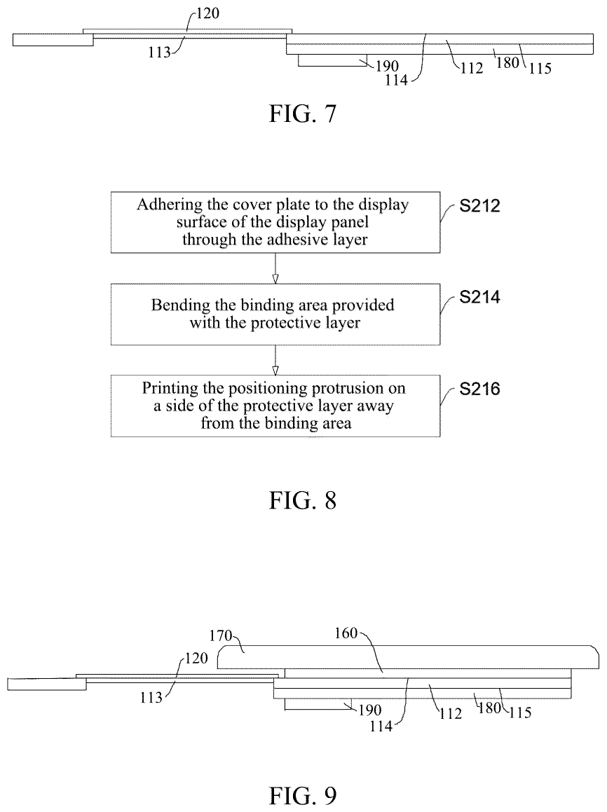

As for the specific structure of the display module 100, the above description can be referred to and will not be repeated here. The specific steps of the method for manufacturing a display module may refer to FIGS. 6 and 7, which may be as follows.

At step S100, the protective layer 120 is disposed in the binding area 113.

The protective layer 120 functions in protecting the binding area 113 and can be waterproof and moisture-proof, the protective layer 120 needs to completely cover the outer side of the binding area 113, and the protective layer 120 may be formed on the binding area 113 by coating. In an exemplary embodiment, a coating material may be coated to the outer side of the binding area 113 to form the protective layer 120. The protective layer 120 may also be formed by printing. In an exemplary embodiment, a printing material is printed on the outer side of the binding area 113 to form the protective layer 120.

At step S200, the cover plate 170 is adhered to the display surface 114 of the display panel 110 by the adhesive layer 160, the positioning protrusions 140 are printed on a side of the protective layer 120 away from the binding area 113, and the binding area 113 is bent.

After the protective layer 120 is disposed, it is necessary to dispose the protective layer 120 in the binding area 113 and bend the binding area 113. Before bending, the connection between the binding area 113 and the display area 112 is located below the cover plate 170. When the positioning protrusions 140 are disposed first, there are requirements for the size of the positioning protrusions 140 to avoid interference between the positioning protrusions 140 and the display panel 110. Different manners may be selected according to different sizes of the positioning protrusions 140, and two manners will be described in detail, where steps S212 to S216 are for one manner and steps S321 to S325 are for the other manner.

Referring to FIG. 8, step S200 may include step S212, step S214, and step S216.

Referring to FIGS. 8 and 9, at step S212, the cover plate 170 is adhered to the display surface 114 of the display panel 110 through the adhesive layer 160.

The display panel 110 includes a display area 112 and a binding area 113, and the display area 112 has a display surface 114 and a non-display surface 115 disposed oppositely. First, the cover plate 170 is adhered to the display surface 114 of the display panel 110 through the adhesive layer 160. The cover plate 170 protrudes from the display surface 114, that is, the cover plate 170 completely covers the display surface 114 and has an area larger than that of the display surface 114.

There is no sequence between step S100 and step S212, and step S100 may be executed first and then step S212 is executed, or step S212 may be executed first and then step S100 is executed. Alternatively, step S100 and step S212 may be executed simultaneously.

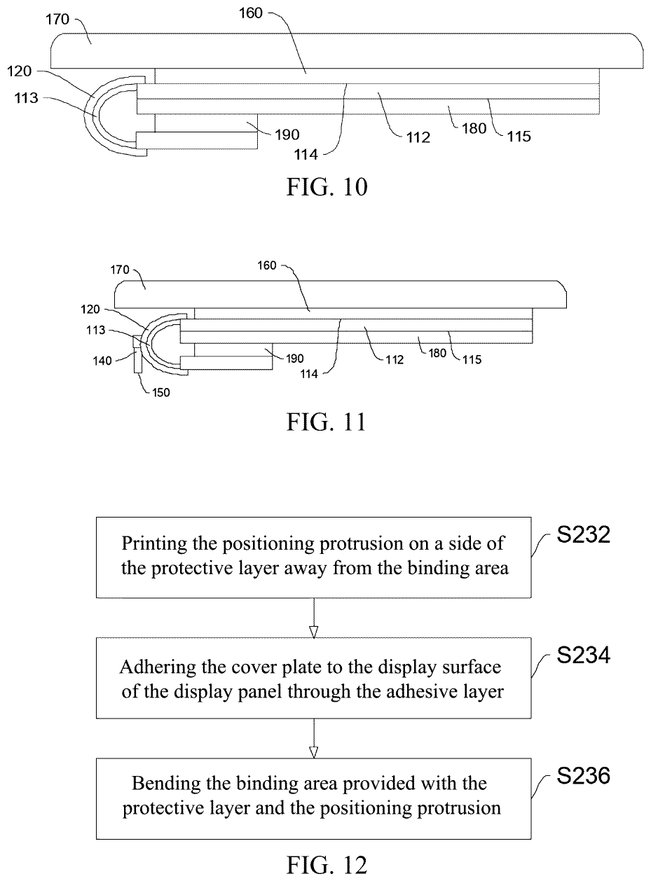

Referring to FIGS. 8 and 10, at step S214, the binding area 113 provided with the protective layer 120 is bent.

After the protective layer 120 is disposed, the binding area 113 and the protective layer 120 are integrally bent, so that at least a part of the binding area 113 can be bent to a side of the non-display surface 115, thereby facilitating the arrangement of electronic components of the display panel 110.

Referring to FIGS. 8 and 11, at step S216, the positioning protrusions 140 is printed on a side of the protective layer 120 away from the binding area 113.

After the protective layer 120 and the binding area 113 are integrally bent, the positioning protrusions 140 are printed on a side of the protective layer 120 away from the binding area 113. This manner is suitable for a case where the height sum of the positioning protrusion 140 and the protective layer 120 is larger than the spacing distance between the display surface 114 and the cover plate 170, and interference between the positioning protrusions 140 and the cover plate 170 can be avoided.

Alternatively, the case where the height sum of the positioning protrusion 140 and the protective layer 120 is smaller than the spacing distance between the display surface 114 and the cover plate 170 may be set in the manner of steps S212 to S216.

Referring to FIG. 12, in addition to this, step S200 may further include step S232, step S234, and step S236.

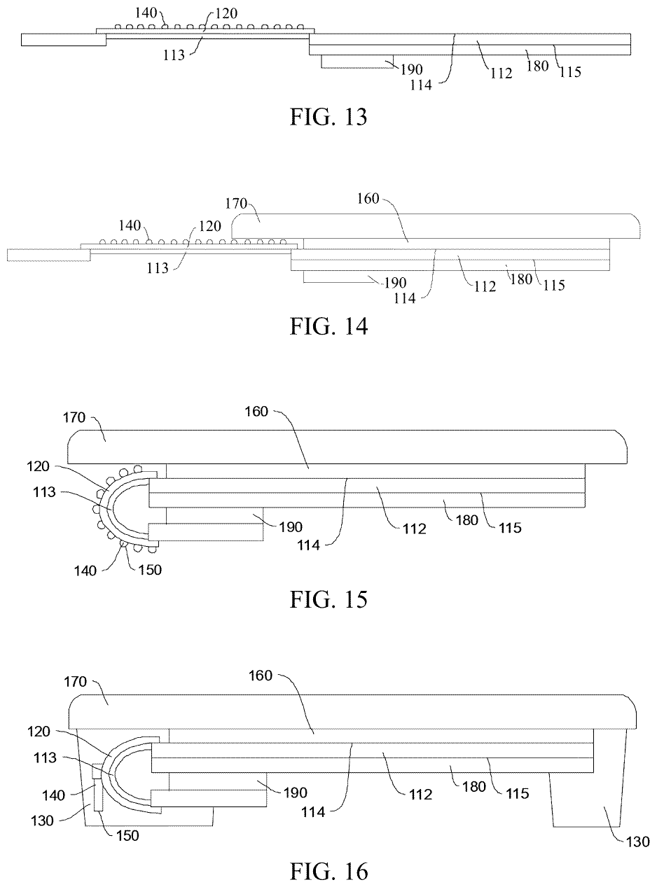

Referring to FIGS. 12 and 13, at step S232, the positioning protrusions 140 are printed on a side of the protective layer 120 away from the binding area 113.

The positioning protrusions 140 may be first printed on the outer side of the binding area 113 before bending the binding area 113. Since the protective layer 120 and the positioning protrusions 140 are disposed before bending the binding area 113, it is necessary to avoid interference between the positioning protrusions 140 and the cover plate 170, and it is necessary to ensure that the height sum of the positioning protrusion 140 and the protective layer 120 is smaller than the spacing distance between the display surface 114 and the cover plate 170. That is, the case where the height sum of the positioning protrusion 140 and the protective layer 120 is smaller than the spacing distance between the display surface 114 and the cover plate 170 may employ the manner of steps S232 to S236.

In addition, the protective layer 120 and the positioning protrusions 140 may be integrally printed, which means that the protective layer 120 and the positioning protrusions 140 are provided simultaneously by printing. Various sequences are included, which may be printing the protective layer 120 first and then printing the positioning protrusions 140, or may be simultaneously printing the protective layer 120 and the positioning protrusions 140. By integrally forming the protective layer 120 and the positioning protrusions 140, the number of manufacturing processes can be reduced, and the positioning accuracy of the positioning protrusions 140 on the protective layer 120 can be improved by printing.

Referring to FIGS. 12 and 14, at step S234, the cover plate 170 is adhered to the display surface 114 of the display panel 110 through the adhesive layer 160.

The display panel 110 includes a display area 112 and a binding area 113, and the display area 112 has a display surface 114 and a non-display surface 115 disposed oppositely. First, the cover plate 170 is adhered to the display surface 114 of the display panel 110 through the adhesive layer 160. The cover plate 170 protrudes from the display surface 114, that is, the cover plate 170 completely covers the display surface 114 and has an area larger than that of the display surface 114.

Referring to FIGS. 12 and 15, at step S236, the binding area 113 provided with the protective layer 120 and the positioning protrusions 140 is bent.

After printing the positioning protrusions 140, the binding area 113, the positioning protrusions 140, and the protective layer 120 are integrally bent, so that at least a part of the binding area 113 can be bent to a side of the non-display surface 115, thereby facilitating the arrangement of electronic components of the display panel 110.

That is, the embodiment of the present disclosure provides two arrangement manners of the positioning protrusions 140. Steps S312 to S316 can be adapted to two cases where the height sum of the positioning protrusion 140 and the protective layer 120 is less than the spacing distance between the display surface 114 and the cover plate 170, and the height sum of the positioning protrusion 140 and the protective layer 120 is greater than or equal to the spacing distance between the display surface 114 and the cover plate 170. While steps S232 to S236 are only adapted to one case where the height sum of the positioning protrusion 140 and the protective layer 120 is less than the spacing distance between the display surface 114 and the cover plate 170.

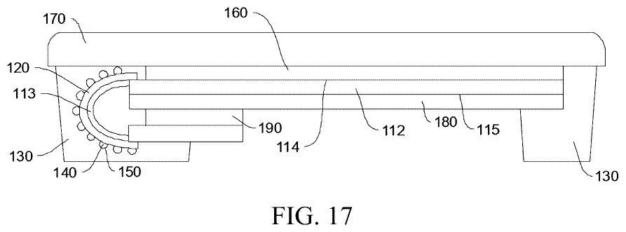

Referring to FIGS. 6, 16, and 17, at step S300, the encapsulation layer 130 is printed around the periphery of the display panel 110 so that the encapsulation layer 130 forms the positioning grooves 150 fitted with the positioning protrusions 140.

The encapsulation layer 130 is disposed on the protective layer 120 by printing. Since the positioning protrusion 140 protrudes from the protective layer 120 during printing, the shape of the positioning protrusion 140 can be adapted by filling the periphery of the positioning protrusion 140 with printing material. By forming the positioning groove 150 adapted to the positioning protrusion 140 on the encapsulation layer 130, the adaption between the positioning protrusion 140 and the positioning groove 150 can be improved, and the mismatch between the positioning protrusion 140 and the positioning groove 150 can be reduced as much as possible. Additionally, the contact area between the positioning protrusion 140 and the positioning groove 150 can be increased, and the risk of bad conditions occurring in the entire display module 100 can be reduced as much as possible, thereby prolonging the service life of the display module 100.

In summary, in the method for manufacturing a display module provided by the embodiment of the present disclosure, by printing the positioning protrusions 140 on the protective layer 120 and then printing the encapsulation layer 130 on the outer side of the positioning protrusions 140, the contact area between the binding area 113 and the encapsulation layer 130 is enhanced, thereby increasing the action area between the binding area 113 and the encapsulation layer 130. When subjected to an external force, by the fitting between the positioning protrusions 140 and the positioning grooves 150, the action force between the protective layer 120 and encapsulation layer 130 is increased, the possibility of the relative displacement between the encapsulation layer 130 and binding area 113 is reduced, thereby reducing the risk of damage to the display module 100, and prolonging the service life of the entire display module 100.

An embodiment of the present disclosure further provides a display device which includes the display module 100 described above. The display device may be a display device having an interactive function such as an electronic whiteboard, or a household appliance having a display function, or a wearable device, or the like.

In the description of the specification, the description with reference to the terms “an embodiment”, “some embodiments”, “examples”, “specific examples”, or “some examples” or the like means that the specific features, structures, materials, or characteristics described in conjunction with the embodiments or examples are included in at least one embodiment or example of the present disclosure. In the specification, schematic expressions of the above terms do not necessarily refer to a same embodiment or example. Moreover, the specific features, structures, materials, or characteristics described may be combined in any one or more embodiments or examples in a proper way. Further, those skilled in the art may integrate and combine different embodiments or examples described in this specification.

In addition, the technical solutions in any embodiments may be combined with each other, but must be on the basis that the person of ordinary skill in the art can realize it. When the combination of technical solutions leads to mutual contradictions or cannot be realized, it should be considered that the combination of technical solutions does not exist and is not within the scope of protection claimed by the present disclosure.

Although implementations of the present disclosure have been illustrated and described, those of ordinary skill in the art may understand that multiple changes, modifications, substitutions, and variations may be made to these implementations without departing from principles and purposes of the present disclosure. The scope of the present disclosure is defined by the claims and their equivalents.

1. A display module, comprising:
a display panel comprising a display area and a binding area connected to the display area;
a protective layer covering an outer side of the binding area; and
an encapsulation layer arranged around a periphery of the display panel;
wherein one of the protective layer and the encapsulation layer is provided with a positioning protrusion, the other of the protective layer and the encapsulation layer is provided with a positioning groove, and the positioning protrusion is embedded into the positioning groove.

2. The display module according to claim 1, wherein when the protective layer is provided with the positioning protrusion, a connection area between the positioning protrusion and the protective layer is smaller than a projected area of the positioning protrusion on the protective layer.

3. The display module according to claim 1, wherein when the protective layer is provided with the positioning protrusion, a height of the positioning protrusion with respect to the protective layer is less than or equal to 300 um.

4. The display module according to claim 1, wherein a maximum width of a projected area of the positioning protrusion on the protective layer is less than or equal to 300 um.

5. The display module according to claim 1, wherein a plurality of positioning protrusions are provided, and the plurality of positioning protrusions are disposed on the protective layer or the encapsulation layer.

6. The display module according to claim 5, wherein two adjacent positioning protrusions are spaced apart by a distance of less than or equal to 5 um.

7. The display module according to claim 5, wherein any two of the positioning protrusions have the same shape or different shapes.

8. The display module according to claim 1, wherein a cross-sectional shape of the positioning protrusion is at least one of a T-shape, an L-shape, a rectangular shape, a circular shape, a trapezoid shape, a triangular shape, and an arc shape.

9. The display module according to claim 1, wherein the positioning protrusion is in printing connection with the positioning groove.

10. The display module according to claim 1, wherein the display module further comprises an adhesive layer and a cover plate, the adhesive layer adheres the cover plate and a display surface of the display panel, and a height sum of the positioning protrusion and the protective layer is smaller than a spacing between the display panel and the cover plate.

11. The display module according to claim 1, wherein when the protective layer is provided with the positioning protrusion, the positioning protrusion and the protective layer are integrally formed by printing.

12. The display module according to claim 1, wherein when the protective layer is provided with the positioning protrusion, the positioning protrusion is in printing connection with the protective layer.

13. The display module according to claim 1, wherein a material of the protective layer is the same as or different from that of the positioning protrusion.

14. A method for manufacturing a display module, comprising:
providing a protective layer in a binding area of a display panel, wherein the protective layer is formed by printing or by coating;
adhering a cover plate to a display surface of the display panel through an adhesive layer, printing a positioning protrusion on a side of the protective layer away from the binding area, and bending the binding area; and
printing an encapsulation layer around the display panel so that the encapsulation layer forms a positioning groove that fits with the positioning protrusion.

15. The method for manufacturing the display module according to claim 14, wherein adhering the cover plate to the display surface of the display panel through the adhesive layer, printing the positioning protrusion on the side of the protective layer away from the binding area, and bending the binding area, comprises:
adhering the cover plate to the display surface of the display panel through the adhesive layer;
bending the binding area provided with the protective layer; and
printing the positioning protrusion on the side of the protective layer away from the binding area.

16. The method for manufacturing the display module according to claim 14, wherein adhering the cover plate to the display surface of the display panel through the adhesive layer, printing the positioning protrusion on the side of the protective layer away from the binding area, and bending the binding area, comprises:
printing the positioning protrusion on the side of the protective layer away from the binding area;
adhering the cover plate to the display surface of the display panel through the adhesive layer; and
bending the binding area provided with the protective layer and the positioning protrusion.

17. A display device, comprising the display module according to claim 1.

18. The display module according to claim 2, wherein the positioning protrusion is in printing connection with the positioning groove.

19. The display module according to claim 2, wherein the display module further comprises an adhesive layer and a cover plate, the adhesive layer adheres the cover plate and a display surface of the display panel, and a height sum of the positioning protrusion and the protective layer is smaller than a spacing between the display panel and the cover plate.

20. The display module according to claim 2, wherein when the protective layer is provided with the positioning protrusion, the positioning protrusion and the protective layer are integrally formed by printing.
